(19) United States
(12) Patent Application Publication
(10) Pub. No.: US 2026/0165112 A1
(43) Pub. Date: Jun. 11, 2026

(54) METALLURGY STRUCTURE FOR HYBRID BONDING

(71) Applicants: International Business Machines Corporation, Armonk, NY (US); The Research Foundation for the State University of New York, Albany, NY (US)

(72) Inventors: Roy R. Yu, Poughkeepsie, NY (US); Katsuyuki Sakuma, Fishkill, NY (US); Nicholas Alexander POLOMOFF, Hopewell Junction, NY (US); Junghyun Cho, Vestal, NY (US); Sari Al Zerey, Johnson City, NY (US)

(21) Appl. No.: 18/974,984

(22) Filed: Dec. 10, 2024

(51) Int. Cl. H01L 23/532; H01L 21/768; H01L 23/522

(52) U.S. Cl. CPC H10W 20/4424; H10W 20/043; H10W 20/42

(57) ABSTRACT

A hybrid semiconductor structure having a mixed nanotwin (nt) structure, including a nt-<111> grain orientation and other oriented grains, e.g., <200> and/or <220> grains. Such mixed nanotwin stacks including <111>/(hkl), where hkl=220, 200, or 220/200, allow a selective etch to form nanometer level surface steps, thereby reducing the contact areas and providing a nanoscale surface roughness that is favorable for contact (high compression) and facilitate the local yielding and grain growth. That is, a low index <200><220> grains structure and a selective etch is used to form favorable bonding surface and improve bonding strength. Using the microstructure of Cu pads and a surface pretreatment process (prior to the bonding), the bonding quality will be improved and permit wider hybrid bonding process window. Further, the pad-to-pad variation will be reduced since the tailored grain growth during the post bonding annealing will make the post bonded microstructures more consistent.

### BACKGROUND

This disclosure relates generally to semiconductor chips or dies having hybrid bonded layers, and more specifically to a novel metallurgical bonding structure used for hybrid bonding of semiconductor chips, chiplets or dies and further methods for providing such metallurgical bonding structure.

In semiconductor chips/chiplets, metal structures such as pads, wires or metal vias fabricated on a Si chip/chiplet lie in a layer having a surface co-planar with a dielectric material surface. Hybrid bonding refers to the bonding of chip/chiplet layers having different surface material structures including, e.g., Cu metal pads or vias and interlevel dielectric (ILD) material, at room temperature and at the same time. Unlike solder joining, Cu via bonding is through solid-state diffusion and mechanical deformation. Dielectric bonding is through surface monolayer silanol (Si—OH)-Silanol→Si—O+H₂O. To ensure monolayer bonding, the Cu via and ILD surfaces are known to require atomically flat and smooth surface.

To facilitate the 3D stacking of semiconductor chips, vertical interconnection schemes become essential. Hybrid bonding enables such an integration between chips through a strong bond made between the dielectric layers (e.g., SiO₂) embedded with an array of Cu pads. The bonded top and bottom chips are initially prepared through the dielectric-dielectric bonding by compressing the two Si chips, which is followed by post annealing that makes the recessed top and bottom Cu pads expand and contact each other to make the Cu—Cu bonding under a compressive stress via diffusion and mechanical deformation. In particular, Cu/SiO₂ hybrid bonding will enable an ultrafine-pitch scaling between pads, making possible very high density interconnects that are critically needed in artificial intelligence (AI) chips. For success in hybrid bonding with the pitch spacing, e.g., below 1 μm, Cu pads need ideal surface preparations, microstructural features, and grain orientations to form the desirable Cu—Cu bonding with no voids or gaps present along the bonding interface.

Current hybrid bonding chips show inconsistencies from pad to pad connections. In addition, bonded Cu pads often show poor quality due to the presence of voids and gaps along the bonded interface.

### SUMMARY

Embodiments of the present disclosure provide a metal bonding structure having a nano-twin (nt) metal (e.g., copper or Cu) portion mixed with the metal of another grain orientation in a semiconductor chip/chiplet die (or chip stack/chiplet stack) that is to be hybrid bonded to another die above or below it.

In a further aspect there is provided a Cu-filled via or pad structure formed at a surface of an interlevel dielectric layer of the chip or chiplet die (or chip stack/chiplet stack) to be bonded using a hybrid bonding technique, the Cu via or pad structure having a mix of structures including a nt-Cu<111> and grains of another crystal orientation.

In this aspect, an electroplating technique is utilized to achieve the Cu via or pad structure having a mix of structures, i.e., a mixed nt-Cu<111> and Cu<hkl> nano-twins stacks (i.e., not pure <111> stacks) where <hkl> represents the other crystal orientations of the metal grains, e.g., Cu<200> or Cu<220> grains.

In an embodiment, the mixed nt-Cu<111> structure with Cu<200> and/or Cu<220> grains is provided and a special etch process is performed to selectively etch other low index Cu<200> and/or Cu<220>.

In a further aspect there is provided a hybrid bonding method for bonding a Cu via or pad structure formed at a surface of a layer of the chip or chiplet die (or chip stack/chiplet stack) to another Cu via or pad structure be bonded, the Cu via or pad structure being a mix including a nt-Cu<111> and a Cu<200> structure, Cu<220> structure or an nt-Cu<111> structure mixed with both Cu<200> and Cu<220> grains.

In this aspect, the bonding of the hybrid pads using a low index grain structure including an nt-Cu<111> structure mixed with both Cu<200> and Cu<220> grains achieves a high bonding yield. Facilitating this high bonding yield, prior to bonding, the method includes conducting a selective etch process that lowers the surface of the Cu<200> and Cu<220> grains structure and forms a selective surface that is favorable for hybrid bonding.

In an embodiment, a particular grain mix of an nt-Cu<111> structure with Cu<200> and/or Cu<220> grains is provided and the method selectively treats the surface with reduced Cu<200> and/or Cu<220> grain components to form a nanoscale surface roughness that is favorable for local contact (high compression) and that facilitates the localized yielding and grain growth. That is, a higher index Cu<200> and/or Cu<220> grains structure and a selective etch is used to form favorable bonding surface.

According to an aspect of the present disclosure, there is provided a semiconductor interconnect structure. The semiconductor interconnect structure comprises: a conductive metal-containing material structure comprising a nanotwin (nt) stack structure having a grain mix comprising a nt-<111> crystal orientation grain component and one or more other crystal orientation grain components.

According to a further aspect, there is provided a method of forming an interconnect structure. The method comprises: forming at least one opening in a dielectric material; and forming a conductive metal-containing material nanotwin stack structure in the at least one opening, the conductive metal-containing material nanotwin (nt) stack structure having a grain mix comprising a nt-<111> crystal orientation grain component and one or more of: a <200> crystal orientation grain component, a <220> crystal orientation grain component or both <200> and <220> crystal orientation grain components in the nanotwin stack structure grain mix.

According to a further aspect, there is provided a semiconductor interconnect structure. The semiconductor interconnect structure comprising: a conductive metal-containing material nanotwin (nt) stack structure having a grain mix comprising a nt-<111> crystal orientation grain component and one or more of: a <200> crystal orientation grain component, a <220> crystal orientation grain component or both a <200> and <220> crystal orientation grain component in the nanotwin stack structure grain mix, the conductive metal-containing material structure defining a surface, wherein the <200> crystal orientation grain component, <220> crystal orientation grain component or both <200> and <220> crystal orientation grain components have a recessed surface relative to a top surface of the <111> crystal orientation grain component.

Further features, as well as the structure and operation of various embodiments, are described in detail below with reference to the accompanying drawings. In the drawings, like reference numbers indicate identical or functionally similar elements.

### BRIEF DESCRIPTION OF THE DRAWINGS

FIG. 1 depicts a nanotwinning phenomena in materials identified in grain boundaries as a shifted segment of a crystal in which the crystal lattices on each edge are linked across an imaginary twin plane by mirror symmetry;

FIG. 2 depicts a microstructure design produced by electroplating techniques under conditions that can form a mix of nt-Cu<111> nanotwin grains and including other oriented grains, e.g., <200> or <220> oriented grains according to an embodiment of the present disclosure;

FIGS. 3A-3D show respective example cases employing the microstructure including depiction for each case, of the surface condition of a microstructure and the resulting microstructure after contacting surfaces of each microstructure for each surface condition case;

FIG. 4 depicts a method of forming a hybrid bond of two Cu microstructures formed in accordance with an aspect of the present disclosure; and

FIG. 5 depicts a Cu plating Winand diagram that depicts the Cu growth structure in current density (i.e., mass transfer characteristic along the horizontal/abscissa) vs. the inhibition intensity (diagrams shown along the vertical/ordinate).

### DETAILED DESCRIPTION

According to an aspect of the present invention, there is provided a semiconductor interconnect structure having a conductive metal-containing material structure comprising a nanotwin (nt) stack structure having a grain mix comprising a nt-<111> crystal orientation grain component and one or more other crystal orientation grain components. The nanotwin stack structure having a grain mix allows for a selective etch to form nanometer level surface steps, thereby reducing the contact areas. The reduced contact areas create higher local contact pressure during bonding, resulting in improved bonding.

In an embodiment, the one or more other crystal orientation grain components comprises a <200> or <220> crystal orientation, a percent content of the nt-<111> crystal orientation grain component being greater than the content of either or both the <200> and <220> crystal orientation grain components.

The conductive metal-containing material structure defines a surface, wherein the <200> or <220> crystal orientation grain component has a recessed surface relative to a top surface of the <111> crystal orientation grain component thereby reducing the contact areas. The reduced contact areas create higher contact pressure during bonding, resulting in improved bonding.

In an embodiment, the interconnect structure is subject to a hybrid bonding technique to bond the interconnect structure on a first die with an interconnect structure on a second die, wherein the interconnect structure permits a wider process window for the hybrid bonding.

In a further aspect, there is provided a semiconductor interconnect structure having a conductive metal-containing material nanotwin (nt) stack structure having a grain mix comprising a nt-<111> crystal orientation grain component and one or more of: a <200> crystal orientation grain component, a <220> crystal orientation grain component or both a <200> and <220> crystal orientation grain component in the nanotwin stack structure grain mix, the conductive metal-containing material structure defining a surface, wherein the <200> crystal orientation grain component, <220> crystal orientation grain component or both <200> and <220> crystal orientation grain components have a recessed surface relative to a top surface of the <111> crystal orientation grain component. The nanotwin stack structure having a grain mix of <200> and <220> crystal orientation grain components with a recessed surface relative to a top surface of the <111> crystal orientation grain component. The recessed surface reduces the bonding contact areas thereby creating higher contact pressure during bonding, resulting in improved bonding and that facilitates grain growth.

In a further aspect, there is provided a method of forming an interconnect structure. The method includes: forming at least one opening in a dielectric material; and forming a conductive metal-containing material nanotwin stack structure in the at least one opening, the conductive metal-containing material nanotwin (nt) stack structure having a grain mix comprising a nt-<111> crystal orientation grain component and one or more of: a <200> crystal orientation grain component, a <220> crystal orientation grain component or both <200> and <220> crystal orientation grain components in the nanotwin stack structure grain mix.

Further to this aspect, the method includes performing a selective etch of the conductive metal-containing material nanotwin stack structure in the at least one opening, the selective etching recessing a top surface of the <200> crystal orientation grain component, <220> crystal orientation grain component or both <200> and <220> crystal orientation grain components relative to a top surface of the <111> crystal orientation grain component.

The nanotwin stack structure having a grain mix allows for the selective etching to form nanometer level surface steps, thereby reducing the contact areas. The reduced contact areas create higher contact pressure during bonding, resulting in improved bonding and that facilitates grain growth.

In this embodiment, the interconnect structure including the nanotwin stack structure is subject to a hybrid bonding technique to bond the interconnect structure on a first die with an interconnect structure on a second die, wherein the interconnect structure permits a wider process window for the hybrid bonding.

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Among the 3D integration techniques, Cu/SiO2 hybrid bonding enables a fine-pitch scaling below 10 μm leading to more powerful devices with high density interconnects that can be used in artificial intelligence (AI) application, quamtum devices and augmented/virtual reality (AR/VR).

Hybrid bonding is made between two chip dies (or wafers or chip die and wafer) by forming the Cu—Cu bonding and the dielectric-dielectric, e.g., SiO2/SiO2 bonding, at the same time. Unlike the solder joining, Cu via bonding is through solid-state diffusion and mechanical deformation. Dielectric bonding is through surface monolayer of silanol (Si—OH)-silanol (Si—OH) reaction into Si—O+H2O. To ensure good bonding, the Cu via and interlevel dielectric (ILD) surfaces are known to require atomically flat and smooth surface.

For success in hybrid bonding with the pitch spacing below 1 μm, Cu pads need ideal surface preparations, microstructural features, and grain orientations to form the desirable Cu—Cu bonding with no voids or gaps present along the bonding interface. The present disclosure provides a system and method to prepare a unique Cu microstructure and surface clean/etch steps prior to the bonding.

In particular, the present disclosure provides a system and method to achieve a void-free bonding interface with a robust bonding strength. To achieve this, the system and method of the present disclosure address the factors influencing the bond quality such as the evenness of the Cu/SiO2 surfaces, the recess depth of Cu pads, the initial grain size and grain orientation of the Cu pads, the bonding and annealing temperatures, and the precise alignment of the top and bottom copper pads.

In prior methods, hybrid bonding of the metal such as copper (Cu) utilize a stacked nanotwin colony, i.e., only nanotwin (nt)-<111> grain structures, or alternatively, multiple orientation grains without stacked nanotwin structures. As a Cu<111> surface has higher modulus, a flat <111> surface does not favor initial contact bonding to initiate the interdiffusion.

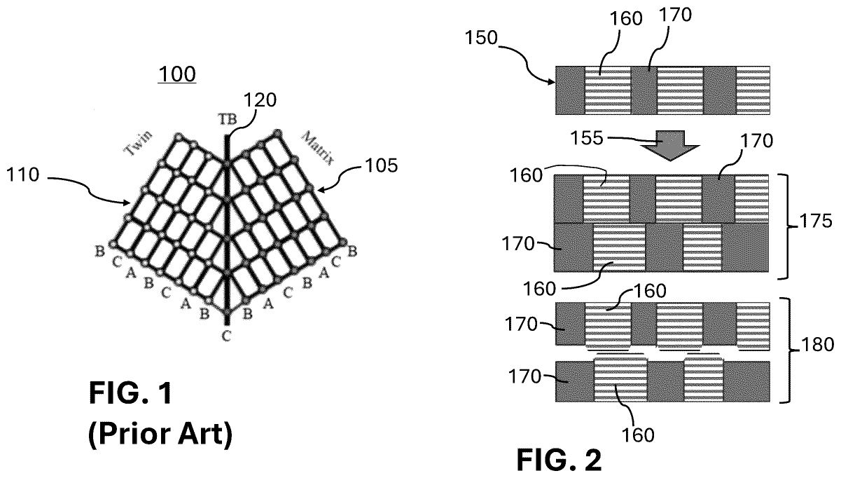

As shown in FIG. 1, a nanotwinning 100 in materials is identified in grain boundaries as a shifted segment of a crystal in which the crystal lattices on each edge are linked across imaginary twin plane by mirror symmetry. As shown in FIG. 1, the nt-metal (e.g., copper or Cu) structure 100 includes a matrix (grain lattice) 105 and a twin (grain lattice) 110 that are grown symmetric to a twinned boundary (TB) 120. As known, nanoscale twin boundary is based on dislocation-TB interaction from mobile and/or sessile dislocations and could be generated either in neighboring domains (twin or matrix) or at the TBs.

In an embodiment, Cu metal nano-twins can form at a 11 plane where the ABCABCAB-C-BACBACBA stack two symmetric directions from the C stack by using pulsed plating. Pulse plating frequency and duty cycle determines the twin thickness. The current density can tilt the twin from normal growth direction. In the electroplating process, applied accelerator, suppressor, and leveler can be used to adjust the twin size, flatness, orientation, which are all important parameters for hybrid bonding.

Thus, according to an embodiment, a new nanotwin Cu plating method is implemented to form a mixed nt-Cu<111> structure in Cu via fills. The mixed nt-Cu<111> structure mixes nanotwin stacks with <111>)/(hkl) (where hkl are the Miller indices) and can be either <220> or, <200> or <220>/<200> or any other grain crystal orientation. Such mixed stacks (<111> and either <220> or, <200> or <220>/<200> oriented grains) allow a selective etch to form nanometer level surface steps, thereby reducing the bonding contact areas. The reduced contact area creates higher contact pressure during bonding, resulting in better bonding. Further, the subsequent anneal favors abnormal grain growth of <220> or <200> that can also remove pre-existing voids.

In one embodiment, specific microstructure features (pre-bonding) are generated from the electroplating processing recipes and an improved resulting bonded microstructure (post-bonding) is obtained from optimal bonding conditions. Examples of pre-bonding and post-bonding Cu microstructures include, for example, pure nanotwin stacks, weakly textured grains with <111>, abnormally grown with <200>, etc. Using the microstructure of Cu pads described herein and implementing its surface pretreatment process (prior to the bonding), the bonding quality will be improved. Further, the pad-to-pad variation will be reduced since the tailored grain growth during the post bonding annealing will make the post bonded microstructures more consistent. Furthermore, a wider hybrid bonding processing window advantageously results from bonding of dies including the microstructures (e.g., Cu vias or pads) of the embodiments herein. That is slight changes in the hybrid bonding process can be accommodated (e.g., using lower temperature anneal) and the process controls can be eased using the interconnect microstructures and pre-bonding surface etching scheme herein.

In accordance with a first embodiment, there is provided a chip or semiconductor die structure that includes a metal via, e.g., Cu metal, subject to a hybrid bonding procedure. In an embodiment, the Cu metal via grain mix includes both a nanotwin (nt) Cu<111> and a Cu<200> or Cu<220> grain orientation. While Cu is the metal material described herein for illustrative purposes, the techniques herein can be used with other metal-containing materials, e.g., including but not limited to Al, W and AlCu or a Cu-containing alloy.

Before employing the hybrid bonding, the Cu<111> nanotwins is mixed with other grain orientations such as Cu<200> and Cu<220> grains. A differential etching is performed among grain orientations (e.g., with less etching on <111> and more etching on <200> and <220> grains (e.g., after an ultrasonic anisotropic etch, e.g., a potassium hydroxide (KOH) etch)). This ensures more grain boundary grooves and removal of chemical mechanical planarization (CMP)-created defects (after ultrasonic KOH etch). The surface etch process is done after the protection layer used to protect the surface of dies/wafers from oxidation, contamination, and dicing debris is removed in acetone or KOH inside an ultrasonic bath. Therefore, the protection layer removal and the surface etching can be done in a single step or in a two-step process. That is, the selective KOH can be combined with the removal process of the protection layer which is coated to protect the wafer surfaces before hybrid bonding (in a single step). Using an ultrasonic bath for the KOH protection layer removal and KOH etching process provides a more efficient single step process. Alternatively, the KOH protection layer removal process can be replaced with first acetone etching in the ultrasonic bath that removes the protection layer but not etching Cu pad surfaces so that the KOH etching process is subsequently applied without any residual organics or contaminants (in a two-step process).

In one aspect, there is provided a mixed grain orientation, e.g., an nt-Cu<111>/<200>/<220> (a nanotwin stack). The method implements such a nt-Cu<111>/<200>/<220> structure mix and performs a special etch to selectively etch only the grains with <200> and <220>. The selective etching (pre-hybrid bonding) creates local and reduced surface areas allowing a higher compressive stress to trigger a local contact yielding to release strain energy during hybrid bonding, which enables more efficient grain growth.

In one aspect, in the Cu metal grain mix having a nt-Cu<111>/<200> grain orientation, by adjusting the surface nt-<111>/<200> ratio, the bonding surface can be appropriately etched into nano-scale topography, which favors the initial bonding and the subsequent annealing to eliminate the bonding voids and enhance bonding strength. Any grains with <100> and <110> orientations are preferentially etched to form flat but nanometer scale surface recesses.

In an embodiment, there is a method for forming an ultra-thin nano-twin structure (on the order of about 10 nm-100 nm) by tailoring electroplating conditions, e.g., using short pulse and reverse current plating. In this embodiment, the twin layers can tilt from normal surface by mixing plating inhibitors and varying the current density J/cm². In an embodiment, forming the nt-<111> grains involves mixing two or more inhibitors in a plating solution to control grain orientation tilt angle (e.g., slightly away from <111>) and using high frequency and short pulse and reverse current to form ultra-thin twin-layers (10 nm-50 nm) in the <111> grains. In the electroplating process, applying an accelerator, suppressor, and leveler can all be used to adjust the twin size, flatness, orientation, which are important parameters for hybrid bonding.

Further, the local and reduced surface areas allow a higher growth (due to lower strain energy) compressive stress during hybrid bonding, enabling a local contact yielding. During anneal, nt-<111> grains thermally bonded first and then yielded: <200>/<220> grains to fill the gaps. The <200>/<220> grains trigger abnormal grain growth.

As shown in FIG. 2 there is depicted a microstructure design 150 produced by electroplating techniques under conditions that can form a mix of nt-Cu<111> nanotwin grains 160 interspersed with other oriented grains, e.g., <200> or <220> oriented grains 170. As a result of bonding/annealing steps 155, there either results in a first intermediate microstructure 175 resulting from a bonding without prior surface etching; or preferably, in accordance with embodiments herein, a resulting second intermediate structure 180 subject to an anneal/bonding after performing a surface differential etching according to embodiments herein that provides a surface texture where the other oriented grains, e.g., <200> or <220> oriented grains 170 have a localized recessed top surface relative to the top surface of the nt-Cu<111> nanotwin grains. The local and reduced surface areas allow a higher compressive stress to trigger a local contact yielding to release strain energy during hybrid bonding, which enables more efficient grain growth. During anneal, the nt-<111> grains thermally bond first and then yielded: <200>/<220> grains to fill the gaps; and <200>/<220> grains trigger abnormal grain growth.

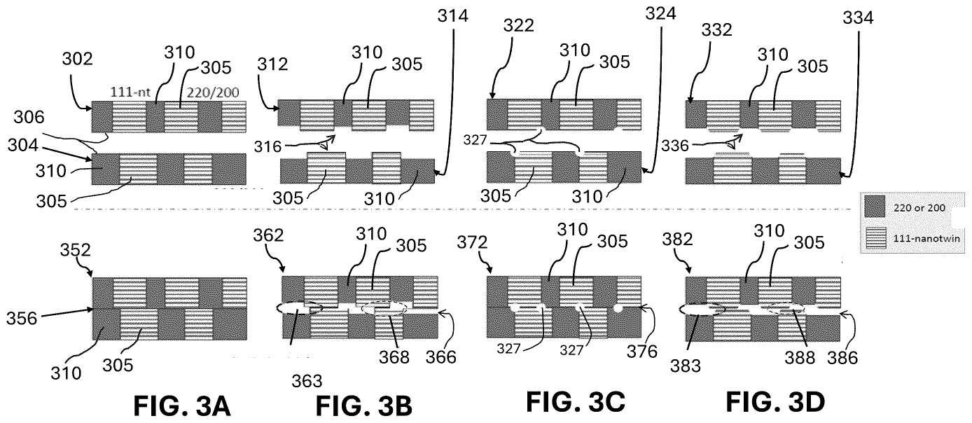

FIGS. 3A-3D show respective example cases employing the microstructure including depiction for each case, of the surface condition of a microstructure and the resulting microstructure after contacting surfaces of each microstructure for each surface condition case.

FIG. 3A shows a first case depicting a first “flat surface” case including two microstructures 302, 304 to be bonded, each structure including a nt-Cu<111> 305 and other grains such as Cu<200> and/or Cu<220> grains 310 that has been processed to exhibit a flat surface condition 306. As shown, the nt-Cu<111> 305 and other grains 310 are aligned and facing each other prior to bonding. On contact, FIG. 3A shows a resulting microstructure 352 having a flat interface 356 on contact.

FIG. 3B shows a second case depicting a “differential grain etching for <220> or <200> grains” case including two microstructures 312, 314 to be bonded, each structure including a nt-Cu<111> 305 and other grains such as Cu<200> and/or Cu<220> grains 310 that have each been processed to exhibit a differential grain surface condition 316 where Cu<200> and/or Cu<220> grain surfaces are recessed relative to the surface of the nt-Cu<111> grains 305. In embodiments, there is a nanometer scale difference in surface heights/depths between the nt-<111> grain components and either/both the <200> and/or <220> metal grain components. As shown, the nt-Cu<111> 305 and other grains 310 are aligned and facing each other prior to bonding. On contact, FIG. 3B shows a resulting microstructure 362 having a “zig-zag” interface 366 on contact. In the zig-zag interface 366, the spaces 363 can be filled by local deformation and surface diffusion and at the interface 368 of the nt-Cu<111> 305 grains requires a higher bonding pressure in a hybrid bonding scheme.

FIG. 3C shows a third case depicting a “flat surface with initial voids” case including two microstructures 322, 324 to be bonded, each structure including a nt-Cu<111> 305 and other grains such as Cu<200> and/or Cu<220> crystal oriented grains 310 that have been etched at the grain boundaries to exhibit voids 327 at interfaces between the Cu<200> and/or Cu<220> grains surfaces and the surface of the nt-Cu<111> grains 305. As shown, the nt-Cu<111> 305 and other grains 310 are aligned and facing each other prior to bonding. On contact, FIG. 3C shows a resulting microstructure 372 having a flat interface 376 with the isolated voids 327 on contact.

FIG. 3D shows a fourth case depicting a “differential grain and grain boundary etching” case including two microstructures 332, 334 to be bonded, each structure including a nt-Cu<111> 305 and other grains such as Cu<200> and/or Cu<220> grains 310 that have each been processed to exhibit a differential grain surface condition 336 where localized Cu<200> and/or Cu<220> grain top-layer surfaces are recessed relative to the surface of the nt-Cu<111> grains 305. As shown, the nt-Cu<111> 305 and other grains 310 are aligned and facing each other prior to bonding. On contact, FIG. 3D shows a resulting microstructure 382 having a “zig-zag” interface with integrated voids 386 on contact. In the zig-zag interface with integrated voids 386, the spaces 383 can be filled by local deformation and surface diffusion and at the interface 388 of the nt-Cu<111> 305 grains requires a higher bonding pressure in a hybrid bonding scheme.

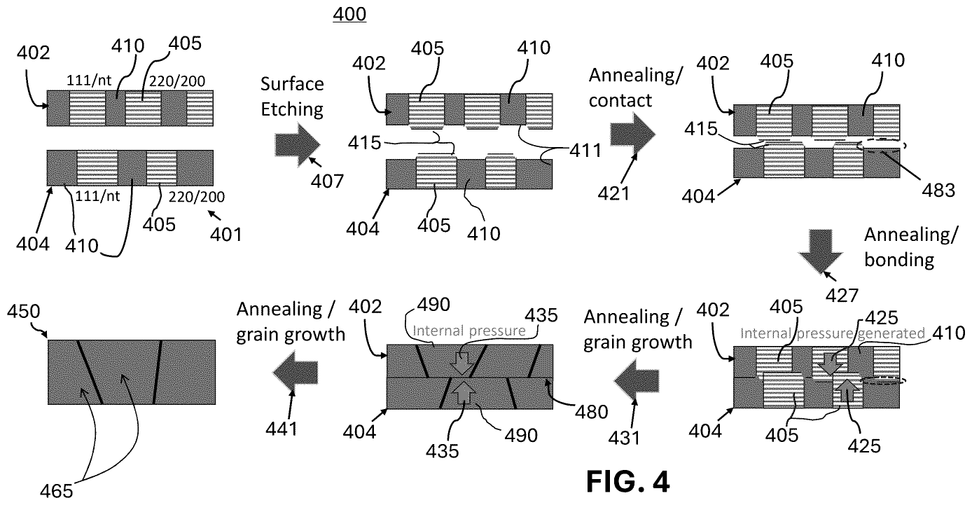

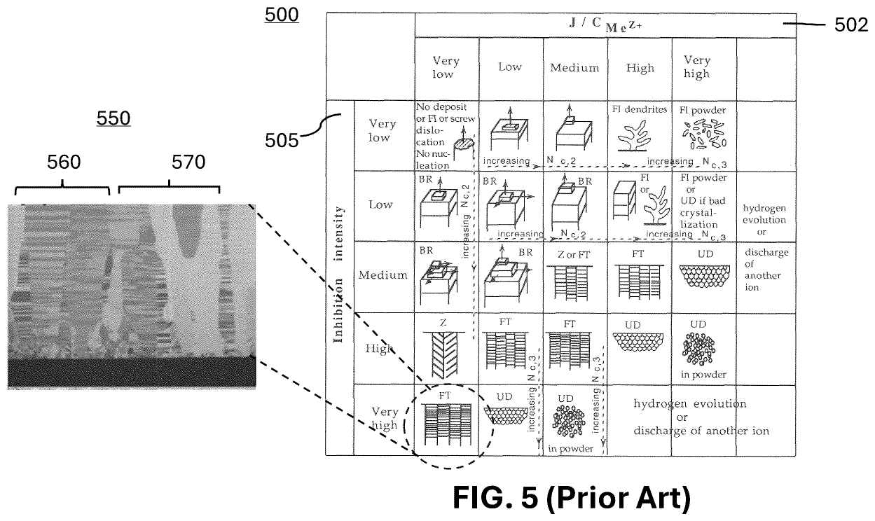

FIG. 4 generally depicts a hybrid bonding method 400 of two metal-containing structures 402, 404 according to an aspect of the present disclosure. In FIG. 4, a first step 401 includes providing and aligning two wafers or semiconductor dies each having a respective metal-containing structure 402, 404 to be hybrid bonded. Both first and second metal-containing structures 402, 404 can be a pad or a via structure of sub-micron through several μmin diameter, each having a conductive metal-containing material (e.g., Cu) including a nanotwin stack structure having a grain mix comprising a nt-<111> crystal orientation grain component 405 (e.g., Cu) and another Cu metal grain component 410 including one or more of: a <200> crystal orientation grain component, a <220> crystal orientation grain component or both a <200> and <220> crystal orientation grain component 410 in the nanotwin stack structure grain mix. In an embodiment, the structures 402, 404 are part of a respective hybrid Cu-SiO₂ die and can be a bond pad that can be sub-1 μm-10 μmin diameter sandwiched between adjacent interlevel dielectric material (e.g., SiO₂) layers (not shown). In both structures, the nt-<111> crystal orientation grain content is greater than the content of the <200> and <220> crystal orientation grain components. In a non-limiting example, a hybrid structure can include grain mix including a 90% nt-<111> crystal orientation grain content and a 10% content of the <200> and <220> crystal orientation grain components. By adjusting surface nt-<111>/<200> ratio, the bonding surface can be appropriately etched into nano-scale topography which favors the initial bonding and the subsequent annealing to eliminate the bonding voids and enhance bonding strength.

The Cu bond pads 402, 404 can be formed according to electroplating techniques described herein, including a mixing of two or more inhibitors in the plating solution to control grain orientation tilt angle (e.g., slightly away from <111>) and the use of high frequency and short pulse and reverse current to form ultra-thin twin-layers (e.g., 10 nm-50 nm) in <111>, a nanotwin <111> plus other crystal oriented grains, e.g., <200>, <220> of the formed Cu bond pad. The process of record (POR) process can remain unchanged, and the hybrid bonding surfaces can be subject to POR CMP and cleaning. Prior to activation and bonding, the bond pad surfaces are etched with solution which preferentially etch on certain areas, such as in <200>, <220> grains and grain boundaries, such that non-nanotwin areas are recessed, grain boundaries are grooved, and initial voids are removed. This is performed by slightly etching (e.g., by the two-steps method, where removal of a protection layer is done using sonication in acetone, followed by sonication in KOH for surface etching, or the single-step method, where removal of a protection layer and surfaced etching are done at once using a single sonication in KOH) on certain grains and/or along the grain boundary to form localized top-layer recessed surfaces. That is, each Cu bond pad 402, 404 has a particular grain mix, e.g., nt-<111>, or other crystal oriented grains, e.g., <200>, <220> grain components, and the surface has been selectively treated (etched) with reduced <200>/<220> component to form a surface texture (i.e., reduced surface areas where local Cu<200> and/or Cu<220> grain surfaces are recessed relative to the surface of the nt-Cu<111> grains) that is favorable for contact (high compression) and facilitate the grain growth. That is, the Cu bond pads provide low index <200> and/or <220> grains and use selective etch to form the favorable bonding surface. At 401, the two dies are aligned such that the Cu bond pads 402, 404 (and dielectric layers not shown) of each die overlie each other.

FIG. 5 depicts a Cu plating Winand diagram 500 detailing the processing recipes for growing a Cu structure by electroplating as a function of current density 502 (i.e., mass transfer characteristic along the horizontal/abscissa) vs. the inhibition intensity 505 (diagrams shown along the vertical/ordinate). The Winand diagram provides the processing recipe to form a mix of crystal orientation (grain mix) the include a nanotwin stack, e.g., nt-<111> with other grain orientations in the mix. For example, to achieve a 90% content of nt-<111> crystal orientation and 10% content of <200> or <220> grain growth the conditions of the electroplating solution require a very high inhibition intensity to obtain the nt-<111> nanotwin structure (a field-oriented texture type) as shown in the ordinate axis and a lower mass transfer characteristic, i.e., lower value of J/ [symbol] where J is the current density and [symbol] is the bulk concentration of metal ion to be discharged (i.e., diffusion limiting current density). Tailoring of these inhibition intensity and current density values will produce a nanotwin microstructure 550 including the desired mix of the nt-Cu<111> nanotwin structure component 560 with another crystal orientation grain component 570, e.g., Cu<200> or Cu<220>, to achieve improved bonding of Cu material containing structures. The regulating of the orientation and distribution of Cu nanotwins grains (grain mix ratio) can be used by techniques such as regulating plating current (AC/DC/pulsing) and by using additives, e.g., using trace gelatin.

Returning back to FIG. 4, in a next step, there is performed a surface etch process 407 of both the first conductive structure 402 and second conductive structure 404. An initial etch is first conducted to remove a surface protection layer (not shown) of each first conductive structure 402 and second conductive structure 404. The surface etch process entails conducting a further differential grain etching for the <220>/<200> grain components and a grain boundary etching. The differential etching among grain orientations refers to less etching on <111> grains and more etching on <200> and <220> grains. As a result of the surface differential etch process, the <200> crystal orientation grain component, <220> crystal orientation grain component or both <200> and <220> crystal orientation grain components 410 have a recessed surface 411 relative to a higher modulus top surface 415 of the <111> crystal orientation grain component 405. In a non-limiting embodiment, the preferential etching is conducted using anisotropic etch such as a KOH etch on both <200> and <220> crystal orientation grain components 410 of each first and second conductive structures 402, 404. As a result of this step, initial voids are modified or filled by the dissolution of Cu surface. Further, plastic yielding becomes easier along the <111> direction on localized contacts. In an embodiment, the differential etching results in more grain boundary grooves and removal of CMP-created defects (e.g., after ultrasonic KOH etch). Thus, as a result of the differential surface etching, the <111>/<200> mix allows a selective etch to form nanometer-level surface steps and reduced contact areas. The reduced surface area facilitates subsequent higher contact pressure during bonding, resulting in a better yield.

Continuing the hybrid bonding process, in a next step 421, FIG. 4, there is depicted a microstructure resulting after a manipulating of the first conductive structure 402 and second conductive structure 404 to contact each other prior to bonding and annealing. Given the recessed top surface boundaries of the <220>/<200> grain components 410, the resulting structure depicted in FIG. 4 shows electrical and local mechanical contact at the top surfaces 415 of each the <111> crystal orientation grain components 405 of the first conductive structure 402 and second conductive structure 404. As shown, the resulting microstructure is of a “zig-zag” interface on contact where the top surfaces 415 of each the <111> crystal orientation grain components 405 of the first conductive structure 402 and second conductive structure 404 are offset thereby creating voids or spaces 483.

Continuing the hybrid bonding process, in a next step 427, FIG. 4, there is depicted a microstructure resulting after a conducting an annealing/bonding step. In an embodiment, the hybrid bonding process tool makes the local contacting at the interface of the Cu pad surfaces 415 of the bonded Cu bond pads 402, 404 upon annealing to generate an internal pressure. Here, the bonding of the pads 402, 404 use the low index grains to achieve a high bonding yield. As shown at step 427, a compressive bonding pressure (e.g., about 340-150 MPa with 1-3 nm recess depths, respectively, for 1 μm thick Cu pads when annealed at 300° C.) can be generated to bond together the first conductive structure 402 and second conductive structure 404. Given the reduced (local) contact area of the nt-<111> grain components, a higher contact pressure results at those interface contact areas (at the same applied process used in hybrid bonding). As a result of the annealing/bonding process step 427, there is generated an internal pressure 425 that locally deforms the <111> grain that fills the interface gaps/voids 483. The resulting microstructure shows the <111> grain filling the voids/spaces 483 by local deformation and surface diffusion. That is, in one embodiment, the subsequent anneal of the mixed nt-Cu<111> and Cu<200> nano-twins stacks favors higher <200> direction solid state diffusion, removing potential voids. In an embodiment, the annealing can be at an anneal temperature of about 200° C.-400 degrees C. The hybrid bonding process additionally bonds the SiO₂ dielectric material structures (not shown) of both dies.

In an embodiment, the hybrid bonding process tool at 427 can make the local contacting at the interface of the Cu pad surfaces of the bonded Cu bond pads upon annealing to generate high internal pressure. Here, the bonding of the pads 402, 404 use the low index grains to achieve a high bonding yield. The protruded surface layer twins produce a higher compression force during bonding anneals, when the Cu metal expands and meets with another Cu metal, initiating the diffusion bonding. That is, the local and reduced surface areas allow a higher compressive stress to trigger a local contact yielding to release strain energy during hybrid bonding, which enables more efficient grain growth.

Continuing the hybrid bonding process of FIG. 4, there is depicted a microstructure resulting after a further annealing/grain growth step 431 of the bonded conductive structures 402, 404. By further annealing at 431, further internal pressure 435 is generated to facilitate <200>/<220> grain growth 490 that results in absorbing the nt-<111> grains. Thus, the process steps in the method 400 of FIG. 4 result in the ability to provide abnormal grain growth on the <200> or <220> grains resulting in a complete change from the pre-bonding microstructure to the post-bonding microstructure after the bonding. That is, after grain growth 490, the resulting post-bonding microstructure exhibits increased mixing, i.e., more interdiffusion, more mechanical deformation which provides for good bonding and will completely remove or shift initial bonding interface.

Continuing the hybrid bonding process of FIG. 4, there is depicted a final microstructure 450 resulting after a further annealing/grain growth step 441 of the bonded conductive structures. Here, during hybrid bonding anneal, more deformable and expandable <200> or <220> grain components grow across the bonding interface 480, sealing any gaps between the twin plateaus. That is, during hybrid bonding process anneal, the nt-<111> grains thermally bond first and then yield: <200>/<220> grains to fill the gaps and <200>/<220> grains trigger abnormal grain growth. The structure 450, FIG. 4, depicts the hybrid bonding process that promotes grain vertical growth 465 in the <200> or <220> direction in accordance with embodiments of the present disclosure.

As hybrid bonding is the direction for future high density chiplets packaging, the embodiments herein address a critical challenge of reducing surface areas of interconnect structures (e.g., vias, pads, wires) to facilitate hybrid bonding contact surface yielding. Currently, a state of art I/O density is 10 μm pitch (e.g., 10K/mm² I/O density). For AI applications, I/O density is targeted for 1 μm pitch or less (e.g., 1M/mm² I/O density). The provision of a nt-Cu<111>/Cu<200>/Cu<220> interconnect structure mix and use a special etch to selectively etch only certain low index grains <200> and <220>, i.e., a selective etch that reduces the <200> and <220> structure and form a selective surface that is favorable for hybrid bonding provides for higher yielding I/O hybrid bonding, e.g., for AI chiplets with pitch close to and below 1 μm pitch.

In the discussion and claims herein, the term “about” indicates that the value listed may be somewhat altered, as long as the alteration does not result in nonconformance of the process or device. For example, for some elements the term “about” can refer to a variation of ±0.1%, for other elements, the term “about” can refer to a variation of ±1% or ±10%, or any point therein. For example, the term about when used for a measurement in mm, may include +/0.1, 0.2, 0.3, etc., where the difference between the stated number may be larger when the state number is larger. For example, about 1.5 may include 1.2-1.8, where about 20, may include 18.0-22.0.

As used herein, the term “substantially”, or “substantial”, is equally applicable when used in a negative connotation to refer to the complete or near complete lack of an action, characteristic, property, state, structure, item, or result. For example, a surface that is “substantially” flat would either completely flat, or so nearly flat that the effect would be the same as if it were completely flat. “Substantially” when referring to a shape or size may account for manufacturing where a perfect shapes, such as circular or sizes may be difficult to manufacture.

As used herein terms such as “a”, “an” and “the” are not intended to refer to only a singular entity, but include the general class of which a specific example may be used for illustration. As used herein, terms defined in the singular are intended to include those terms defined in the plural and vice versa.

As used herein, when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

References in the specification to “one aspect”, “certain aspects”, “some aspects” or “an aspect”, indicate that the aspect(s) described may include a particular feature or characteristic, but every aspect may not necessarily include the particular feature, structure, or characteristic. Moreover, such phrases are not necessarily referring to the same aspect. Further, when a particular feature, structure, or characteristic is described in connection with an aspect, it is submitted that it is within the knowledge of one skilled in the art to affect such feature, structure, or characteristic in connection with other aspects whether or not explicitly described.

While the figures herein illustratively demonstrate exemplary structures and processing steps, according to specific embodiments of the present invention, it is clear that a person ordinarily skilled in the art can readily modify such structures or process steps for adaptation to specific application requirements, consistent with the above descriptions.

It should therefore be recognized that the present invention is not limited to the specific embodiments illustrated hereinabove, but rather extends in utility to any other modification, variation, application, and embodiment, and accordingly all such other modifications, variations, applications, and embodiments are to be regarded as being within the spirit and scope of the invention.

What is claimed is:

1. A semiconductor interconnect structure comprising:
a conductive metal-containing material structure comprising a nanotwin (nt) stack structure having a grain mix comprising a nt-<111> crystal orientation grain component and one or more other crystal orientation grain components.

2. The semiconductor structure of claim 1, wherein the one or more other crystal orientation grain components comprises a <200> or <220> crystal orientation, a percent content of the nt-<111> crystal orientation grain component is greater than the content of either or both the <200> and <220> crystal orientation grain components.

3. The semiconductor structure of claim 2, wherein the conductive metal-containing material structure defines a surface, wherein the <200> or <220> crystal orientation grain component has a recessed surface relative to a top surface of the <111> crystal orientation grain component.

4. The interconnect structure of claim 1 comprising a conductive via or a pad having said conductive metal-containing material.

5. The interconnect structure of claim 1 wherein said conductive metal-containing material comprises Cu, Al, W and AlCu or a Cu-containing alloy.

6. The interconnect structure of claim 5, wherein said via structure or pad comprise a reduced surface contact area for improved bonding and grain growth.

7. The interconnect structure of claim 5, subject to a hybrid bonding technique to bond the interconnect structure on a first die with an interconnect structure on a second die, wherein said interconnect structure permits a wider process window for said hybrid bonding.

8. A semiconductor interconnect structure comprising:
a conductive metal-containing material nanotwin (nt) stack structure having a grain mix comprising a nt-<111> crystal orientation grain component and one or more of: a <200> crystal orientation grain component, a <220> crystal orientation grain component or both a <200> and <220> crystal orientation grain component in the nanotwin stack structure grain mix, the conductive metal-containing material structure defining a surface, wherein the <200> crystal orientation grain component, <220> crystal orientation grain component or both <200> and <220> crystal orientation grain components have a recessed surface relative to a top surface of the <111> crystal orientation grain component.

9. The semiconductor structure of claim 8, wherein a percent content of the nt-<111> crystal orientation grain component is greater than the content of either or both the <200> and <220> crystal orientation grain components.

10. The semiconductor interconnect structure of claim 8 wherein said conductive metal-containing material comprises Cu, Al, W and AlCu or a Cu-containing alloy.

11. The semiconductor interconnect structure of claim 8 comprising a via structure or a pad having said conductive metal-containing material.

12. The semiconductor interconnect structure of claim 11 wherein said via structure or pad comprises a reduced surface contact area for improved bonding and grain growth.

13. A method of forming an interconnect structure comprising:
forming at least one opening in a dielectric material; and
forming a conductive metal-containing material nanotwin stack structure in said at least one opening, the conductive metal-containing material nanotwin (nt) stack structure having a grain mix comprising a nt-<111> crystal orientation grain component and one or more of: a <200> crystal orientation grain component, a <220> crystal orientation grain component or both <200> and <220> crystal orientation grain components in the nanotwin stack structure grain mix.

14. The method of claim 13, wherein a percent content of the nt-<111> crystal orientation grain component is greater than the content of either or both the <200> and <220> crystal orientation grain components.

15. The method of claim 13, further comprising:
performing a selective etch of said conductive metal-containing material nanotwin stack structure in said at least one opening, said selective etching recessing a top surface of the <200> crystal orientation grain component, <220> crystal orientation grain component or both <200> and <220> crystal orientation grain components relative to a top surface of the <111> crystal orientation grain component.

16. The method of claim 15, wherein the selective etch comprises conducting a KOH etch of the conductive metal-containing material nanotwin stack structure in said at least one opening.

17. The method of claim 16, wherein the conducting a KOH etch comprises one of:
using an ultrasonic bath for removing a KOH protection layer coated to protect wafer surfaces in combination with the KOH etch as a single process; or
using an ultrasonic bath with an acetone solution etching to remove the KOH protection layer removal without etching surfaces of the conductive metal-containing material nanotwin stack structure in said at least one opening and subsequently applying the KOH etch without any residual organics or contaminants as a two-step process.

18. The method of claim 13 wherein the forming of the nt-<111> crystal orientation grain component comprises: providing a plating solution; mixing two or more inhibitors in the plating solution to control grain orientation tilt angle; and using high frequency and short pulse and reverse current to form ultra-thin twin-layers in the <111> grain components.

19. The method of claim 13, wherein the formed conductive metal-containing material nanotwin stack structure in said at least one opening comprises a via or a pad structure having a reduced surface contact area for improved bonding and grain growth.

20. The method of claim 19, subject said via or a pad structure to a hybrid bonding technique to bond the via or a pad structure on a first die with an interconnect comprising a via or a pad structure on a second die, wherein said via or a pad structure permits a wider process window for said hybrid bonding.
